(19) United States
(12) Patent Application Publication
(10) Pub. No.: US 2022/0149840 A1
(43) Pub. Date: May 12, 2022

(54) Illuminated Switch

(71) Applicant: CAPTRON ELECTRONIC GMBH, Olching (DE)

(72) Inventors: Christian Rogge, München (DE); Roman Gebhard, München (DE)

(21) Appl. No.: 17/609,580

(22) PCT Filed: May 7, 2020
(86) PCT No.: PCT/EP2020/062774

§ 371 Date: Nov. 8, 2021

(30) Foreign Application Priority Data
May 10, 2019 (EP) 19173699.0
Jul. 5, 2019 (EP) 19184642.7

(51) Int. Cl. H03K 17/96; H03K 17/955; H03K 17/94

(52) U.S. Cl. CPC H03K 17/962; H03K 17/955; H03K 17/9627; H03K 2217/960785; H03K 2217/96015; H03K 2217/96042; H03K 2217/960755; H03K 17/941

(57) ABSTRACT

A sensor switch including a capacitive sensor and/or an optical sensor configured to detect the presence of a body part and a housing defining a mounting plane. The housing further contains at least one lighting window providing a cover for at least one light source that is disposed in the housing. Such light source(s) provide(s) corresponding light beam(s) in a plane parallel to the mounting plane or at an angle with respect to the mounting plane.

### CROSS-REFERENCE TO RELATED APPLICATIONS

This application is a continuation of pending International Patent Application No. PCT/EP2020/062774 filed on May 7, 2020 and now published as WO 2020/229314, which designates the United States and claims priority from European Application No. 19173699.0 filed on May 10, 2019 and European Application No. 19184642.7 filed on Jul. 5, 2019. The disclosure of each of these patent application is incorporated by reference herein.

### BACKGROUND

### 1. Field of the Invention

The invention relates to a switch which is operated by a person or by bringing an object or a body part of a person in close proximity to a sensor or touching said sensor. Such a switch may be a capacitive sensor switch.

### 2. Description of Related Art

### DESCRIPTION OF THE RELATED ART

Switches and specifically capacitively operated sensor switches are often used for operating doors in railways and busses or other public transport systems, or for operating machines. The sensor switches are robust, maintenance-free, easy to use, and can be adapted to many different designs.

Sensor switches are often based on a capacitive sensor technology. A capacitive sensor may detect an approaching object and specifically an approaching body part, which may be a hand or a finger, by capacitively coupling an electrical signal to the object. An approaching object may be detected by an attenuation of the signal voltage or by an increasing signal current flowing through the object.

A switch which may be used for unlocking a door in a public transport is disclosed in US 2005/0231147 A1. Here, the switch is designed as an elongated bar which can easily be recognized due to its size.

A comparatively compact and disk-shaped device is disclosed in DE 197 18 807 Cl. Here, a capacitive sensor is mounted to one side of a public transport window. An indicator ring indicating the sensor area of the switch is mounted at the opposing side of the window. The switch is capacitively operated through the window.

### SUMMARY

The embodiments are providing a switch with increased visibility. Such a switch may be recognized from a larger distance or under poor lighting conditions.

In an embodiment, a switch has a housing including a switching element which may be a mechanical switch. In another embodiment, the switching element includes a sensor which may further include a capacitive and/or optical sensor or which may cover a capacitive and/or optical sensor. Such a sensor switch may also be called a sensor button. Both embodiments may be combined with any of the features described herein. The switching element may be configured for detecting the presence of a body part. The sidewall may be configured to be insensitive against the presence of a body part.

The housing may have a top part and a bottom part. The top part includes a sensor surface on a top side and opposing thereto a mounting section.

Between the sensor surface and the mounting section is a sidewall. The sidewall may have at least one rounded edge or a curved shape.

A switching element is arranged within or under the sensor surface. It may be covered by the sensor surface.

The mounting section may be configured to be mounted to a planar object like a plate which may be a glass plate or a metal structure. The surface of the mounting object may define a mounting plane.

The bottom part extends from the mounting section in a direction opposing to the sensor surface. The bottom part may be one part with the top part or mechanically separated thereof. The top part may be in a fixed spatial relationship to the bottom part. In an embodiment, the top part may not be rotatable against the bottom part in an assembled working configuration. The bottom part may be screwed into the top part for assembly.

The sidewall further includes at least one lighting window. A plurality of lighting windows may be provided. The lighting windows may be symmetrically arranged. For example, if there are two lighting windows, they may be arranged on opposing sides. If there are three lighting windows, these may be arranged at angular separation of 120 degrees around a perimeter of the switch. Four lighting windows may be arranged at angular separation of 90 degrees. Behind the at least one lighting window and within the housing there is at least one light source which is configured to radiate light to the outside of the switch through the corresponding lighting window(s). Such light source(s) may be arranged to ensure that light is radiated towards and onto a surface on which the switch is mounted. This surface may be in the mounting plane, in which case the at least one light source is configured to direct a light beam in parallel to the mounting plane or at an angle to the mounting plane. The surface may reflect the light and may provide a marking of the switch and/or a switch appearance which is larger than the switch itself. In addition, any other part of the housing, e.g. the switching element area may emit light. The emitted light may vary in color and intensity and overtime.

The at least one lighting window may protect the light source from environmental influences and may provide a mechanical and/or electrical shield. It may be a lens or may include at least one lens or lens structure, for example a Fresnel-lens or parts thereof.

The housing has a mounting section, which is configured to be mounted to a surface. The top of the surface defines a mounting plane to which the housing (e.g. the switch) may be mounted. Preferably, the switching element has a planar surface which preferably is parallel to the mounting plane.

The housing may be a one-piece (optionally, monolithic) housing with a preferably threaded shaft for holding the switching element. In another embodiment, the housing includes a top part and a bottom part which may be mounted distant from each other. The top part may be in electrical and/or optical communication with the bottom part.

In at least one embodiment, at least one light source is integrated into the switching element housing. It may also be integrated into an outer ring. In an embodiment, the switching element housing is a two-part embodiment, where the two parts may be mounted at different sides of a window. Here, the switching element and/or sensor electronics may be provided in a first part being on one side of the window, whereas the at least one light source may be disposed in in another part, which may be an outer ring on the other side of the window. Also, a light source for lighting the switching element may be provided. Any of the light sources (including that configured to light the switching element) may be LEDs, OLEDs or other light-emitting devices that are supplied by electrical energy which may be inductively or capacitively coupled from the first part. There may be a coil within the outer ring which is coupled to a coil in the first part to couple the electric energy between the two parts. Alternatively, the light may be emitted by at least one light source which may include a LED or other light-emitting components in the first part and guided for example by a lens system through the glass of the window into the second part like an outer ring where it is deflected to the at least one lighting window to the outside of the housing.

The light sources may have different and/or multiple colors which may indicate different states of the switch or different types or kinds of switches.

### BRIEF DESCRIPTION OF THE DRAWINGS

In the following, the invention will be described by way of example, without limitation of the general inventive concept, on examples of embodiment and with reference to the drawings.

FIG. 1 shows a top view of an embodiment.

FIG. 2 is a perspective view of an embodiment.

FIG. 3 illustrates an embodiment mounted into a window.

FIG. 4 shows a two-part embodiment.

FIG. 5 shows an example of light distribution produced by an embodiment of the switch, in a top view.

FIG. 6 shows an example light beam of the switch.

Generally, the drawings are not to scale. Like elements and components are referred to by like labels and numerals. For the simplicity of illustrations, not all elements and components depicted and labeled in one drawing are necessarily labels in another drawing even if these elements and components appear in such other drawing.

While various modifications and alternative forms, of implementation of the idea of the invention are within the scope of the invention, specific embodiments thereof are shown by way of example in the drawings and are described below in detail. It should be understood, however, that the drawings and related detailed description are not intended to limit the implementation of the idea of the invention to the particular form disclosed in this application, but on the contrary, the intention is to cover all modifications, equivalents and alternatives falling within the spirit and scope of the present invention as defined by the appended claims.

### DETAILED DESCRIPTION

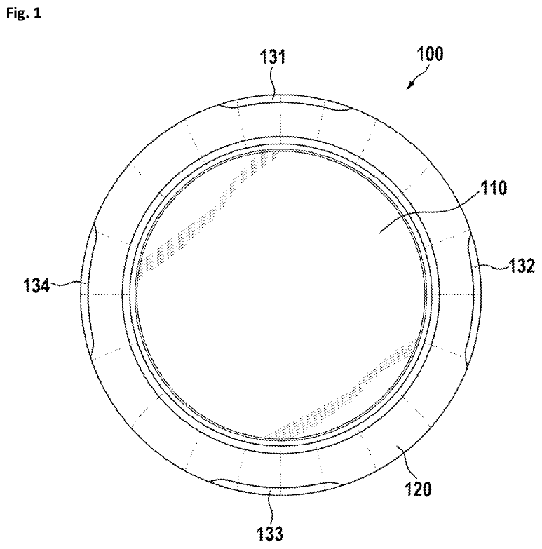

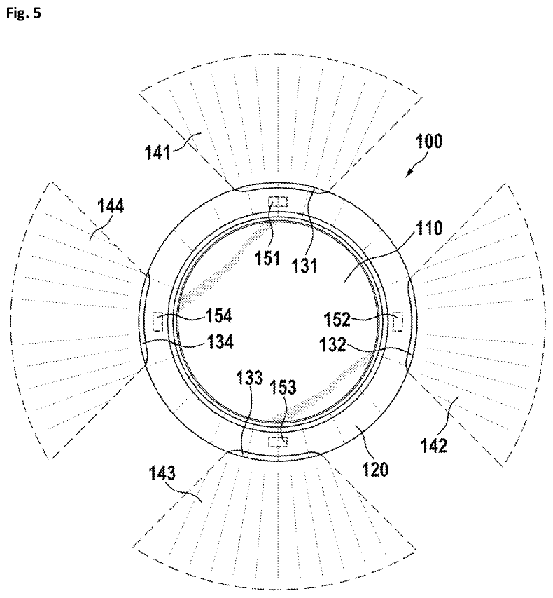

In FIG. 1, a top view of an embodiment is shown. A switch 100 includes a preferably planar switching element 110 or a planar sensor which is sensitive to an approaching object which may be a hand or a finger of a person. Preferably, the switching element 110 is a mechanical or electronic switching device or a capacitive and/or optical proximity sensor. The switching element preferably has a planar surface. There may be an outer ring 120 surrounding the switching element 110. A plurality of lighting windows 131, 132, 133, 134 are provided circumferentially to the switching element and may be integrated into the outer ring 120. Preferably, the lighting windows are arranged symmetrically. In the embodiment shown herein, four lighting windows are provided which are arranged under angles of 90 degrees between adjacent windows. The windows have an elongated shape but they may have any other shape, like a circular shape or a rectangular slot, or any other shape which is suitable for providing a light output. Preferably, the lighting windows include a material which may conduct light of a suitable wavelength. Not shown in this Figure (but in FIG. 5) are light sources 151-154 which provide light which exits through the lighting windows. Preferably, at least one light source is provided within the switch and behind each of the lighting windows. The light sources may be individually controllable to generate various light patterns.

In an embodiment, the lighting windows and/or the sensor surface exclusively are configured to emit light outwards, that is, these elements are the only components of the switch that are configured to transmit light from the light source(s). The outer ring, except for the windows, may include a non-light transmissive and/or a light absorbing material.

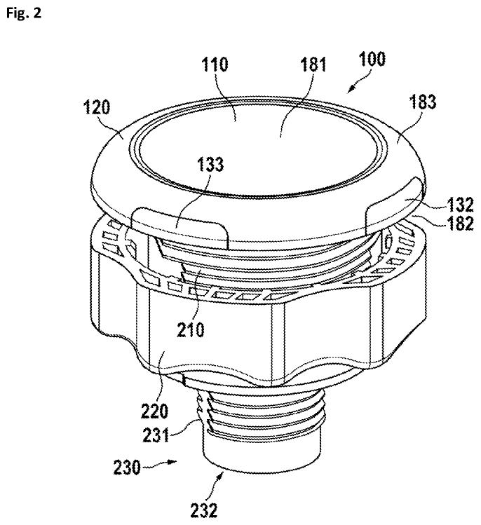

In FIG. 2, a perspective view of an embodiment is shown. In addition to the top of the switch with sensor surface 181, sidewall 183, and mounting section 182, which may have a planar surface configured to be mounted to a surface which may be the top surface of a mounting plate, which will be shown in the next figure. The top surface also defining a mounting plane. The components of the bottom part 102 are also shown. There may be a shaft 210 which may include switching mechanics or electronics or further electronic devices required for capacitive and/or optical detection of an object in close proximity to the sensor 110. The shaft may have an outer thread which matches to a fastening nut 220. At the housing, there may also be a signal connector 230 for electrical connections providing power to the switch and coupling of a detection signal. The connector may have an outer thread 231 and connecting pins 232 which are on the bottom side in this embodiment and cannot be seen.

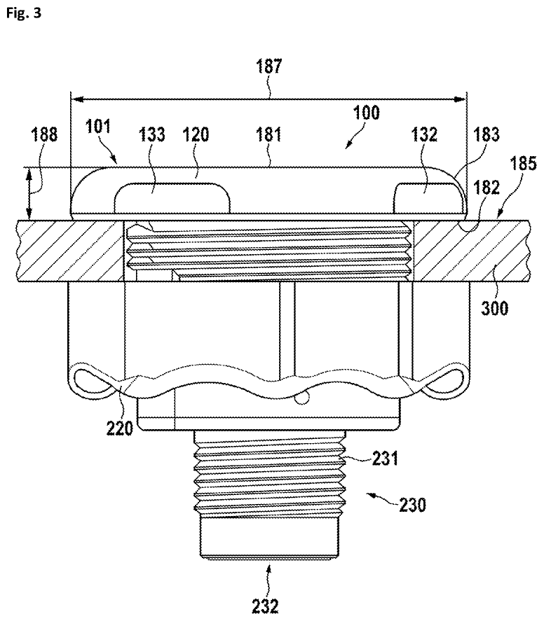

In FIG. 3, an embodiment is shown, which is mounted into a plate 300 which may be a window or a glass plate. The top side of the plate 300 may be defining the mounting plane 185 which is in contact with the mounting section 182. It may also be a window including multiple parallel glass plates. The fastening nut 220 may be rotated to hold the switch within a hole of the window. The mounting plane is the top plane of the plate 300, which preferably corresponds to an under side of the top part of the housing containing the switching element.

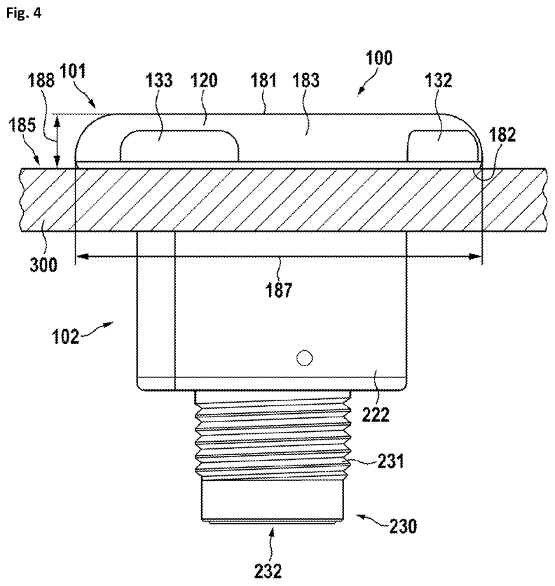

In FIG. 4, a two-part embodiment is shown. Here, the switch 100 includes a top part 101 which is attached on one side of the plate 300, which may be a window, and a bottom part 102 which is mounted opposing to the top part 101 on the other side of the plate 300, which may be a window. The advantage of this embodiment is that there is no hole required in the window. The disadvantage is that coupling of electrical signals and/or sensing of an object may be somewhat more complicated due to the higher coupling distance through the plate, which may be a window, and coupling of light or electrical power for light sources from the second part 102 to the first part 101 may require additional effort as disclosed above. The mounting plane is the top plane of the plate 300, which preferably corresponds to an under side of the top component 101.

The top part 101 may have a width or a diameter 187 which is larger than its height 188. The ratio width-to-height for the part 101 may be chosen to be less than one of 10, 8, 6, 5, 4, 3, 2. The top part 101 may have a circular (disk-like) shape. It may have a diameter 187 which is larger than its height 188. The ratio diameter/height in this case may be smaller than one-to 10, 8, 6, 5, 4, 3, or 2, depending on the specifics of a particular implementation.

In FIG. 5, an example of spatial light distribution produced by the embodiment of the switch is shown in a top view. In addition, here only for demonstration purposes, the light sources 151, 152, 153, 154 are indicated. The lights sources cannot be seen in FIG. 5, as they are embedded (completely cast) into the solid plastic block of the outer ring 120 of the switch. In operation, the light sources radiate light through the lighting windows 131, 132, 133, 134 and generate light beams 141, 142, 143, 144. These light beams are preferably directed at a small angle to the surface on which the switch is mounted, as will be shown in the next Figure.

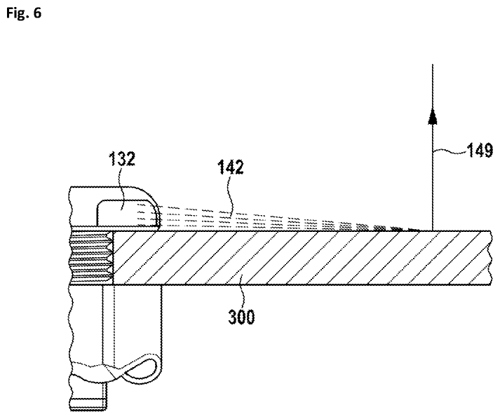

In FIG. 6, an example of the light beam emanating from the switch is shown. Here, light emitted through the lighting window 132 forms a light beam 142 directed at a small angle with respect to and towards the plate 300, which may be a window or a metal plate. The light is reflected by the plate 300 and may be seen by a person, such as a person operating the switch. The best results are provided if the surface of the plate is light reflecting such that the light emitted through the window 132 is emitted in a direction orthogonal to the plate, such as indicated by arrow 149.

It will be appreciated to those skilled in the art having the benefit of this disclosure that this invention is believed to provide an illuminated switch. Further modifications and alternative embodiments of various aspects of the invention will be apparent to those skilled in the art in view of this description. Accordingly, this description is to be construed as illustrative only and is provided for the purpose of teaching those skilled in the art the general manner of carrying out the invention. It is to be understood that the forms of the invention shown and described herein are to be taken as the presently preferred embodiments. Elements and materials may be substituted for those illustrated and described herein, parts and processes may be reversed, and certain features of the invention may be utilized independently, all as would be apparent to one skilled in the art after having the benefit of this description of the invention. Changes may be made in the elements described herein without departing from the spirit and scope of the invention as described in the following claims.

### LIST OF REFERENCE NUMERALS

100 switch
101 top part of housing
102 bottom part of housing
110 switching element
120 outer ring
131-134 lighting windows
141, 142, 143, 144 light beams
149 direction of reflected light
151, 152, 153, 154 light sources
181 sensor surface
182 mounting section
183 sidewall
185 mounting plane
187 width or diameter
188 height
210 shaft
220 fastening nut
230 signal connector
231 outer thread
232 connecting pins
300 mounting plate

1. A switch comprising:
a housing that includes a disc-shaped top part and a bottom part and that houses at least one light source,
wherein the top part comprises:
a sensor surface on a top side of the top part,
a mounting section opposing the sensor surface and configured to be mounted to a planar object having a top surface that defines a mounting plane for mounting of the mounting section thereto, and
a sidewall between the sensor surface and the mounting section, the sidewall comprising at least one lighting window that covers the at least one light source configured to direct a light beam in parallel to the mounting plane or at an angle with respect to the mounting plane,
and
wherein the bottom part extends from the mounting section;
and
a switching element arranged within or under the sensor surface.

2. A switch according to claim 1, wherein the housing of the switch is a one-piece housing containing the switching element and a shaft.

3. A switch according to claim 2, wherein the shaft has an outer thread.

4. A switch according to claim 1, wherein the housing is configured to have the top part and the bottom part thereof mounted vertically distantly from but opposite each other.

5. A switch according to claim 4, wherein the top part is in electrical communication and/or optical communication with the bottom part.

6. A switch according to claim 1, wherein the switching element comprises a light source configured to illuminate the switching element.

7. A switch according to claim 1, wherein said at least one light source is a LED or an OLED.

8. A switch according to claim 1, wherein the switch is a sensor switch and wherein the switching element includes a capacitive sensor and/or optical sensor configured to detect the presence of a body part and/or wherein the sidewall is configured to be insensitive to the presence of the body part.

9. A switch according to claim 1, wherein the sensor surface is parallel to the mounting section.

10. A switch according to claim 1, wherein the sidewall has at least one rounded edge.

11. A switch according to claim 1, wherein a width of the disc-shaped top part larger than a height of the disk-shaped top part.

12. A switch according to claim 1, wherein the at least one lighting window and/or the sensor surface are the only components of the switch that are configured to transmit light.

13. A switch according to claim 1, wherein, when the switch is assembled, the top part is not rotatable against the bottom part.

14. A switch according to claim 8, wherein, when the switch is assembled, the top part is not rotatable against the bottom part.

15. A switch according to claim 10, wherein a width of the disc-shaped top part larger than a height of the disk-shaped top part.

16. A switch according to claim 15, wherein the at least one lighting window and/or the sensor surface are the only components of the switch that are configured to transmit light.
